(19) United States
(12) Patent Application Publication
(10) Pub. No.: US 2010/0276283 A1
(43) Pub. Date: Nov. 4, 2010

(54) Vacuum coating unit for homogeneous PVD coating

(76) Inventors: Wolf-Dieter Muenz, Weiz (AT); Stefan Kunkel, Biebergemund (DE)

Correspondence Address: PROPAT, L.L.C., 425-C SOUTH SHARON AMITY ROAD, CHARLOTTE, NC, 28211-2841, US

(21) Appl. No.: 12/517,515

(22) PCT Filed: Dec. 3, 2007
(86) PCT No.: PCT/EP2007/010476

§ 371 Date: Jun. 29, 2010

(30) Foreign Application Priority Data
Dec. 7, 2006 (DE) 10 2006 058 078.8

(51) Int. Cl. H01J 37/32; C23C 14/35; H01J 37/34

(52) U.S. Cl. 204/298.14; 204/298.16; 204/298.41

(57) ABSTRACT

The apparatus includes a coating chamber, two or more cathodes which are arranged peripherally within the coating chamber, substrate carriers for holding the substrate, vacuum pumps and voltage sources wherein an individual anode is arranged centrally between the cathodes in the coating chamber and the substrate is positioned between the anode and the cathode. In each case a gas discharge with a plasma is ignited between the individual anode and the cathodes. The substrates are held fixed in position or are rotated about one or more axes and in the process subjected to the plasma.

The invention relates to a vacuum coating installation for homogeneous PVD coating of three-dimensional substrates, comprising a coating chamber, two or more magnetron sputtering sources or arc evaporator sources arranged peripherally within the coating chamber a substrate carrier, for holding the substrate, vacuum pumps and voltage sources.

Magnetic-field-assisted cathode sputtering (magnetron sputtering) has become established in many areas of modern surface engineering. Proceeding from applications in microelectronics, magnetic-field-assisted cathode sputtering has become established nowadays as an industrial coating method for architectural glass, flat screens, spectacle lenses, strip materials, tools, decorative objects and functional components. In this case, functional components are often provided with anticorrosion or hard material layers composed of nitrides such as TiN, TiAIN, VN, ZrN, CrN or carbonitrides such as TiCN in single- or multilayer technology. “Superhard” layers on the basis of nano-multilayers having hardness values of up to 50 GPa are increasingly being employed as well. Friction- and wear-reducing metal-carbon layers have proved to be extremely successful in the automotive industry.

Methods and installations for homogeneous coating of planar surfaces such as e.g. silicon wafers or glass panes are technically highly developed and easily controllable. However the layers deposited on three-dimensional substrate bodies-such as e.g. watch cases, writing devices, spectacle frames, cutting and forming tools, medical devices or components in automotive engineering, mechanical engineering and device construction—have microscopic inhomogeneities. These inhomogeneities impair the layer quality and thus the functional properties and the mechanical durability of the coated components.

The inhomogeneities are a consequence of the anisotropy of the plasma used in the coating process. If a three-dimensional substrate is arranged in front of a planar cathode, then the distance between the cathode and the points on the substrate surface is not constant. Furthermore, the front half of the substrate facing the cathode shades the rear side from the plasma of the cathodes and thus from the ion bombardment and also from the material flow. The intensity of the ion bombardment is significantly lower on the rear side of the substrate remote from the cathode than on the front side of the substrate exposed to the plasma of the cathodes. However, a uniform coating of the substrates is required for many applications. One proven method for uniform coating of three-dimensional substrates consists in rotating the substrates in front of the coating source, a specific point on the substrate surface periodically running through regions with intensive and with weak ion bombardment. As a result, a multilayer coating is deposited, comprising layers having thicknesses in the range of from a few nanometers to a few micrometers, depending on the rotational speed and deposition rate. Such an inhomogeneous layer construction influences the microstructure, hardness, intrinsic stress, wear and corrosion resistance and the color of the coating usually in an undesirable manner.

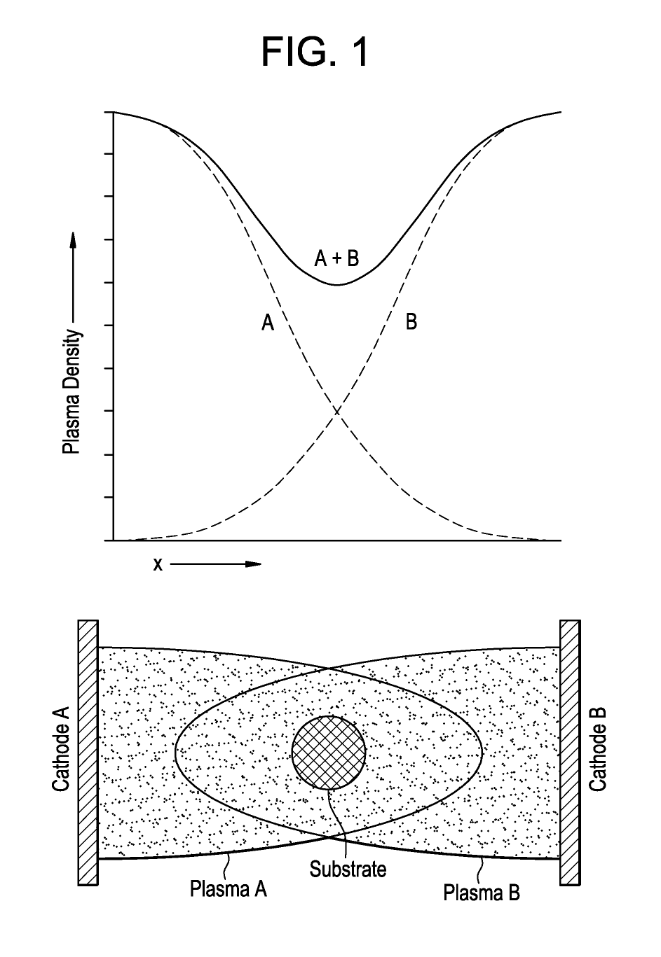

As discussed above, the primary cause of the inhomogeneous layer construction resides in the delimitation of the plasma generated during the magnetron discharge to a spatial zone in front of the cathode. The intensity of the ion bombardment of the growing layer varies with the distance of the substrate surface from the cathode. In the case of substrates having a small depth dimension, this spatial variation can be virtually completely compensated for by positioning the substrates between two mutually opposite cathodes during the coating (see FIG. 1). The plasmas emerging from the two cathodes are superposed in the center, with the formation of a spatial zone with practically isotropic plasma and uniform coating conditions. It is known that e.g. cylindrical substrate bodies up to a diameter of 10 mm can be uniformly coated all around in this way, without requiring special substrate rotation about the cylinder axis.

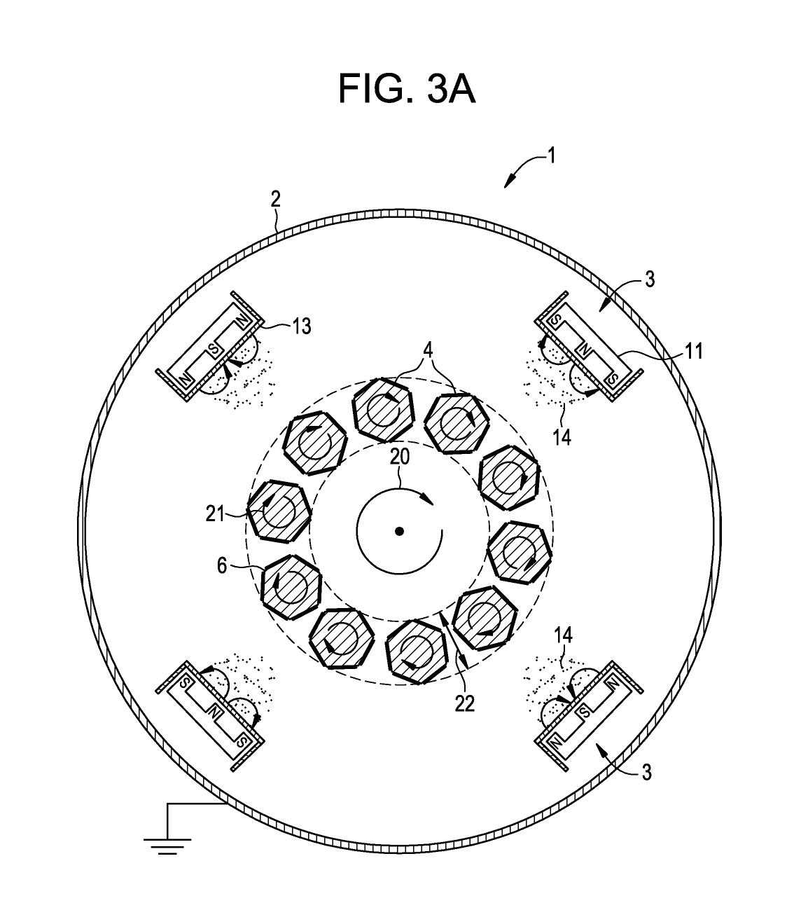

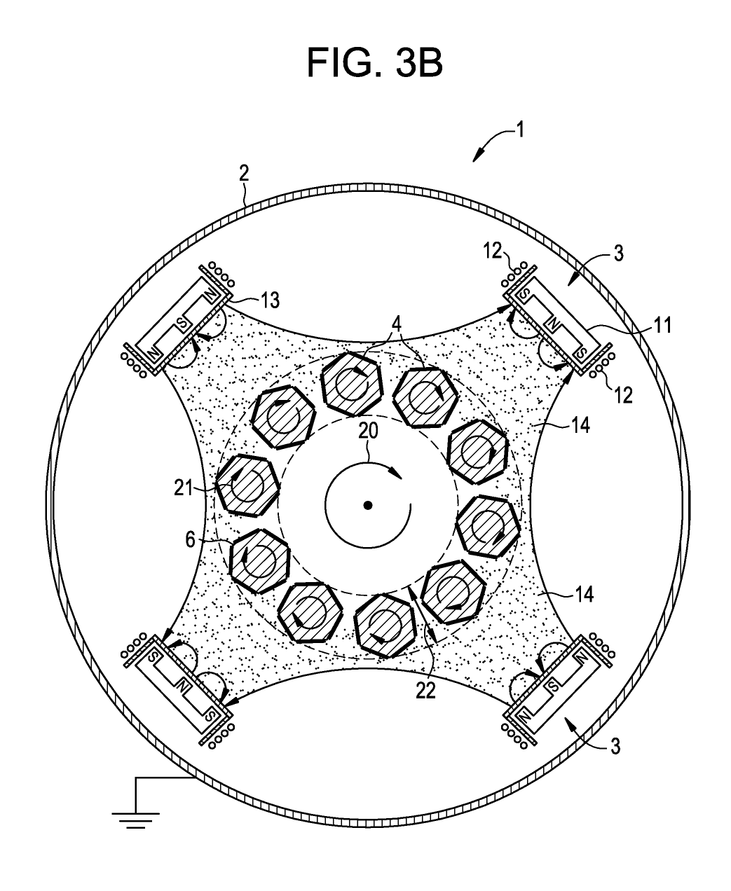

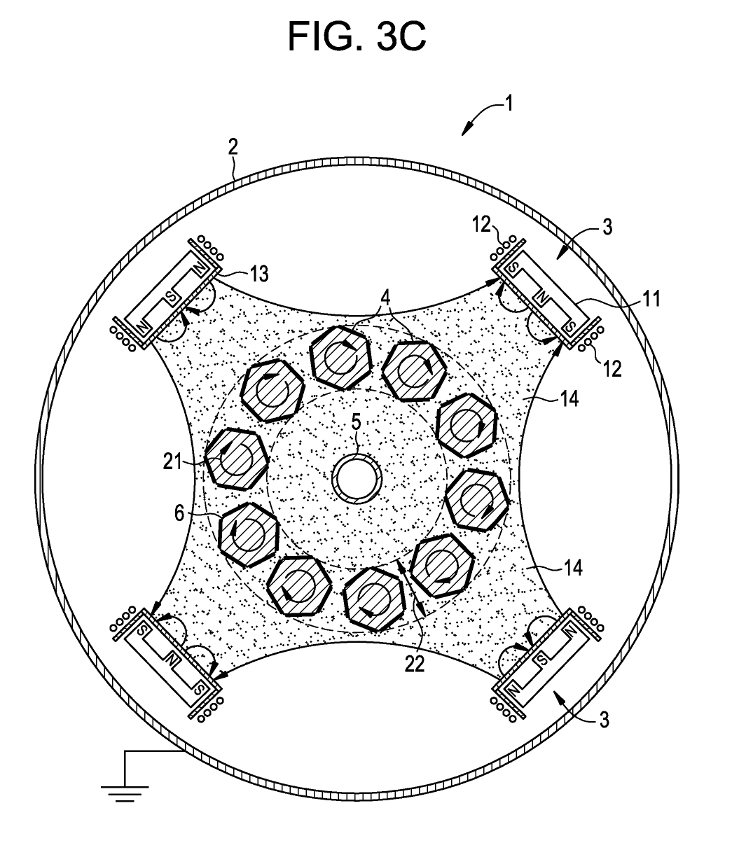

So-called “balanced” planar magnetron cathodes (see FIG. 3a) are equipped with permanent magnets that generate a tunnel-shaped closed magnetic field in front of the target mounted on the cathode. If an electric field is superposed on this closed magnetic tunnel, then the electrons are moved in front of the target on helical paths. This means that the electrons in a spatial volume element cover longer distances than in the case of a cathode without a magnetic field, in the case of which the electrons move along the electric field lines—usually linearly. As a result, the number of collisions between electrons and gas atoms or molecules per spatial volume element increases and the gas ionization increases in association with this, with the formation of an intensive plasma that is enclosed in front of the target in the region of the magnetic tunnel.

Important properties of the deposited layers such as, for example, composition, morphology, adhesion and intrinsic stress are crucially determined by the layer growth on the substrate. It is known that the layer growth and thus the layer properties are influenced by ion bombardment during the coating process. Thus, Thornton (J. A. Thornton, Annu. Rev. Mater. Sci. 7, p. 239, 1977) and Messier (R. Messier, J. Vac. Sci. & Technol., 2, 500, 1984) have investigated in their studies the dependence of the layer structure on gas pressure and ion bombardment during layer growth. Particularly in the case of hard material layers which comprise materials having a high melting point and the layer growth of which is described by the zone T in the structure zone model developed by Thornton and Messier, an intensive ion bombardment is absolutely necessary in order to deposit compact or dense layers. In order to realize an intensive ion bombardment of the substrates, so-called “unbalanced” magnetron cathodes are used in the prior art. In the case of an unbalanced magnetron, a portion of the magnetic field lines is not closed in front of the cathode target, but rather runs in the direction of the coating space in which the substrates are situated. On account of these field components, a portion of the electrons is led in the direction of the substrates, such that the plasma expands toward the substrates. By applying a substrate potential, ions are accelerated from the plasma near the substrate onto the growing layer and the ion bombardment that is advantageous for the layer growth is present.

Examples of methods and apparatuses for cathode sputtering with ion assistance are present in the following prior art.

DE 40 42 289 A1 relates to an apparatus for reactive coating of a substrate, which apparatus comprises a magnetron cathode and a separate anode electrically insulated from the coating chamber. The anode is of ring-like configuration and arranged spatially between the magnetron cathode and the substrate to be coated. The direct visual link between magnetron cathode and anode is prevented by a screen, whereby the coating of the anode is avoided. During reactive coating processes with materials having a high affinity for the reactive gas, the inner walls of the coating chamber, the screens and other built-in components can be coated with electrically nonconductive or poorly conductive coatings. The use of an anode shielded against coating makes it possible in such a case to conduct the coating process stably and in a manner free of arcing, in which case it is not necessary to frequently clean the coating chamber and the built-in components thereof or to frequently replace the built-in components.

WO2006/099760 A2 discloses a vacuum process installation for surface processing of workpieces with an arc evaporation source, which contains a first electrode connected to a DC current supply. The installation contains a second electrode, which is isolated from the arc evaporator source. The two electrodes are in each case connected to a pulsed current supply.

An arc coating installation in accordance with EP 0 534 066 A1 comprises a chamber which contains the parts to be coated and which is equipped with cathodes/evaporators and a first and a second anode. During the coating process, the second anode is held at a potential that is higher than the potential of the first anode. In this case, the substrates are at a negative potential that is greater than the negative potential of the cathode. In the arrangement described, the anodes extract a portion of the electrons from the cathode plasma and accelerate them into the coating chamber. As a result, the ionization of the gases situated in the coating chamber is intensified and the ion bombardment to the substrates is intensified.

The apparatus for coating substrates by means of magnetic-field-assisted low-pressure discharges that is described in U.S. Pat. No. 5,556,519 A comprises two or more magnetron cathodes. The outer magnetic poles of adjacent magnetron cathodes have an opposite polarity and generate a magnetic field cage that practically encloses all the electrons of the low-pressure discharges. As a result, in the space in front of the cathodes, the degree of ionization of the low-pressure discharges is increased and the ion bombardment of the substrates is intensified.

DE 31 07 914 A1 teaches a method and an apparatus for coating a shaped part with a three-dimensional coating area by means of magnetic-field-assisted cathode sputtering, in which the shaped part is arranged between two mutually opposite cathodes and is simultaneously exposed to the plasma clouds of both cathodes. A voltage that is negative with respect to ground potential and is less than/equal to −10 V is applied to the shaped part. The plasmas of the cathodes arranged opposite one another are superposed in such a way that the shaped part is exposed to an ion bombardment that is uniform all around.

DE 38 37 487 A1 discloses a method and an apparatus for etching substrates by means of a magnetic-field-assisted low-pressure discharge. The substrates are arranged between electron emitters and anodes. The electron emitters are surrounded by the magnetic field of a magnetic system that is at ground potential. Negative potentials of 100 to 1000 V are applied to the substrates. The anode potentials are 10 to 250 V. Electrons emerge from the electron emitters heated by means of current and are accelerated toward the anodes. The electrons collide with gas atoms or molecules, gas ions and further electrons being generated by impact ionization. The plasma thus generated expands and penetrates through the substrate arrangement. On account of the negative substrate potential, the positive gas ions from the plasma are accelerated, such that an intensive ion etching of the substrates is obtained.

WO 1998 0 31041 A1 describes an apparatus and a method for setting the ion current density at the substrate. The apparatus comprises a vacuum chamber which is equipped with magnetron cathodes or ionization sources at its outer periphery and which are arranged around a coating zone and in the center of which a magnet arrangement composed of individual permanent magnets is situated. The polarities of the magnet arrangement and of the magnetron cathodes/ionization sources surrounding it can be identically or oppositely directed. In addition, the magnetic field strength of the magnet arrangement and the position or orientation of its individual magnets can be varied. This results in diverse possibilities for setting the magnetic field in the coating zone and, in association with this, for controlling the ionization at the substrate. By way of example, given opposite polarity of the magnet arrangement and of the magnetron cathodes, magnetic field lines are led through the coating zone, which results in an increased ionization at the substrate. The substrates positioned in the coating zone can be coated with or without application of an electrical potential. DC, AC, pulsed DC, MF and RF sources can be used for the electrical supply of the substrates.

In the industrial coating of three-dimensional substrates, the majority of the PVD methods known in the prior art work with highly inhomogeneous discharge plasmas. The layers deposited on three-dimensional substrates by these PVD methods therefore have inhomogeneities. By contrast, some of the known PVD methods and installations comprise measures or apparatuses which have a homogeneous discharge plasma but are associated with considerable apparatus complexity and costs, low substrate throughput and/or a limitation of the substrate thickness.

Accordingly, the object of the present invention is to provide an apparatus which makes it possible to furnish three-dimensional substrates with a homogeneous PVD coating in a cost-effective and effective manner, to increase the ionization of the evaporated material and likewise the electron emission and the ionization of the reactive gas.

This object is achieved by means of a vacuum coating installation of the type described in the introduction in such a way that an individual, central anode is connected to a pulsed voltage source and the respective magnetron sputtering sources or arc evaporator sources are connected to pulsed voltage sources.

In a development of the invention, the magnetron sputtering sources or arc evaporator sources are connected to DC voltage sources.

The further configuration of the invention emerges from the features of claims 3 to 10.

In order to realize a high substrate throughput in conjunction with a compact design, the apparatus according to the invention is preferably equipped with four or six cathodes. In particular, the cathodes are embodied as balanced magnetron cathodes which are operated as unbalanced magnetrons by means of electromagnetic coils arranged concentrically around the magnetron cathodes. Planar rectangular cathodes (linear cathodes) or planar circular cathodes can be used as cathodes.

The anode is preferably distinguished by the fact that it:
is of telescopic construction, such that the anode length can be reduced for the purpose of loading and unloading the coating chamber;
is equipped with a cooling apparatus for compensation of the anode heating by plasmas having a high power density; and
is composed of stainless steel, graphite or metal-encased graphite.

For the purpose of horizontally loading and unloading substrates, the coating chamber is equipped with a laterally arranged vacuum door or vacuum lock.

In one preferred embodiment of the invention, the coating chamber is connected to a recipient for receiving the central anode. In order to protect the anode against contamination during the ventilation of the coating chamber, a valve is installed between the recipient and the coating chamber.

Between the individual, centrally positioned anode and a plurality of cathodes, plasma is generated by means of gas discharges, the substrates being surrounded by plasma during the coating.

According to the invention, the gas discharges are operated in a mode in which the ion bombardment of the substrate zones facing the cathodes and the anodes has an average current density of 0.2 to 8.0 mA/cm², preferably of 0.2 to 5.0 mA/cm², and in particular of 1.0 to 3.0 mA/cm².

The substrates are typically moved during the coating process. In particular, the substrates are led on a circular path centered around the anode between the anode and the cathodes and simultaneously rotate about vertical axes carried along on the centered circular path.

A closed magnetic field is generated by alternating magnetic polarity of adjacent cathodes, the magnetic field enclosing the plasma in the interior of the coating chamber and at a distance from the wall of the coating chamber.

The invention is explained in more detail below with reference to drawings and examples. In the figures:

FIG. 1 shows the plasma distribution of a double cathode;

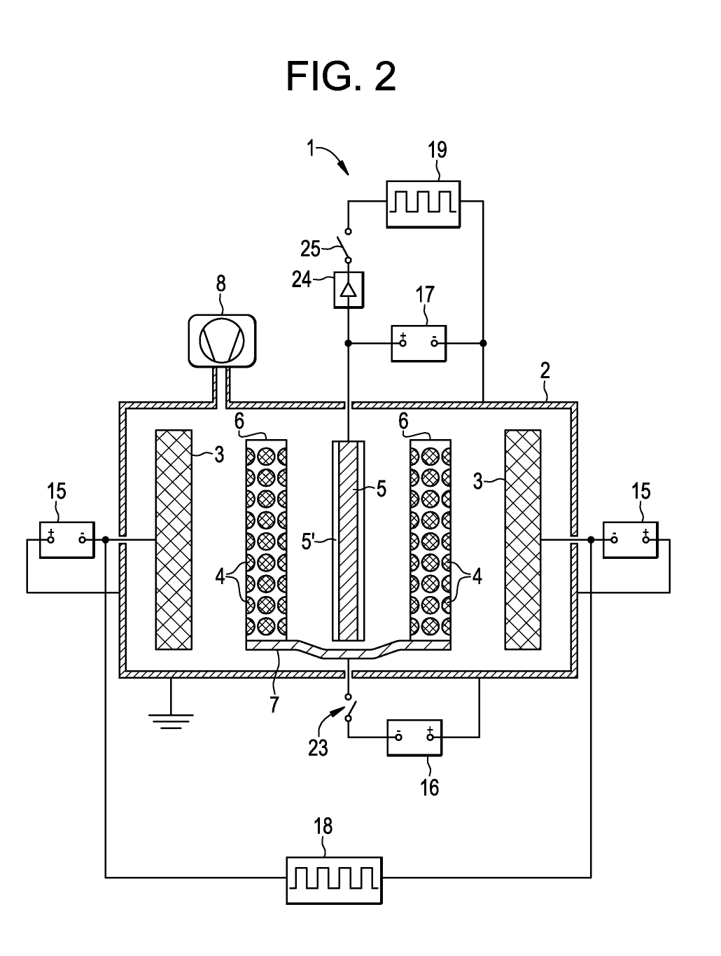

FIG. 2 shows an apparatus according to the invention with a central anode;

FIG. 3a shows the plasma distribution in a known PVD coating installation with balanced magnetron cathodes;

FIG. 3b shows the plasma distribution in a known PVD coating installation with unbalanced magnetron cathodes;

FIG. 3c shows the plasma distribution in an apparatus according to the invention with a central anode;

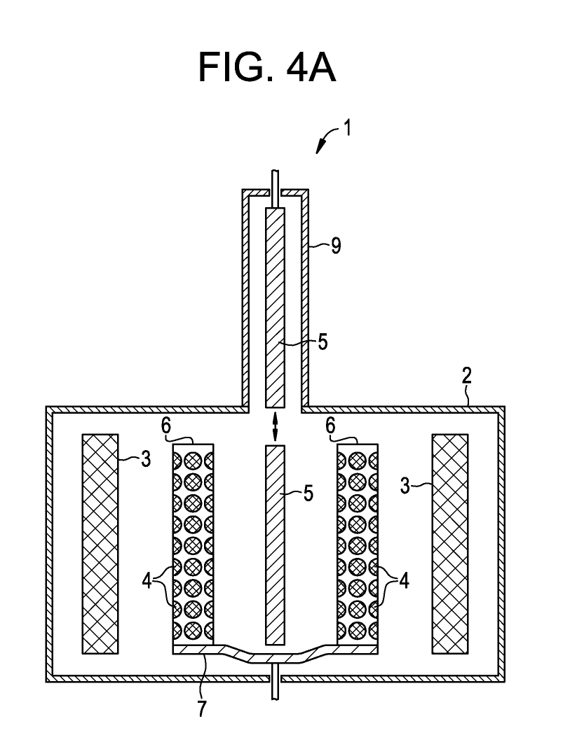

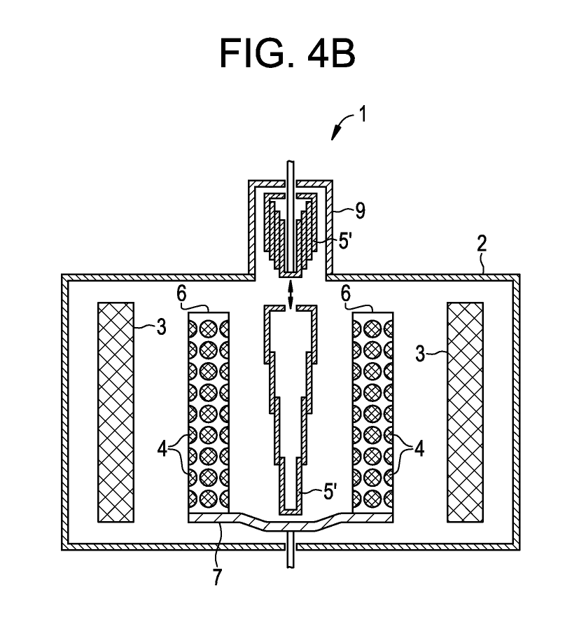

FIG. 4a shows a coating chamber with a recipient for the central anode;

FIG. 4b shows a central anode of telescopic construction.

FIG. 1 illustrates the functioning of the double cathode arrangement known in the prior art. A substrate is positioned centrally between two mutually opposite cathodes A and B. The density of the plasma generated by each individual cathode decreases rapidly with the distance from the cathode, such that each individual plasma A and B acts very differently (anisotropically) on the substrate. By contrast, a spatial zone with a substantially uniform (isotropic) plasma density arises as a result of the superposition of the two plasmas A and B at the location of the substrate.

Magnetron cathodes are preferably used in industrial coating technology. Permanent magnet segments are arranged behind the target that is eroded (sputtered) during the coating process, an inner linear magnet segment being surrounded by an outer ring of magnetic segments having an opposite polarity. This magnet arrangement generates a tunnel-shaped closed magnetic field in front of the target, which magnetic field brings about the enclosure of the discharge plasma during the coating process. A water-cooled carrier plate dissipates the thermal energy generated in the case of high cathode powers at the target surface.

FIG. 2 schematically shows an exemplary embodiment of the apparatus 1 according to the invention. An anode 5 is arranged in the center of a vacuum-tight coating chamber 2. The anode 5 is surrounded by two or more cathodes 3 fitted to the inner wall of the coating chamber 2. The number of cathodes 3 is n where n=2, 4, 6, 8 or 2n+1 where n=1, 2, 3. Substrate carriers 6 equipped with substrates 4 are situated between the anode 5 and the cathodes 3. The substrate carriers 6 are mounted on a rotary table 7 centered axially with respect to the anode 5. The rotary table 7 and the substrate carriers 6 mounted on planetary spindles are driven by means of motors, such that substrate carriers 6 are led through on a circular path between the anode 5 and the cathodes 3 and simultaneously to this rotate about their longitudinal axis.

The rotational speeds of the substrate carriers 6 (ω_{S}) and of the rotary table 7 (ω_{D}) are coordinated such that the average residence duration of each substrate 4 in front of the cathodes 3 is of the same length. This is achieved e.g. if ω_{S} is a multiple of ω_{D}: ω_{S}=m·ω_{D} where m>3. A uniform coating of the substrates is thereby ensured.

The coating chamber 2 is filled with at least one inert or reactive process gas such as e.g. argon, neon, helium or oxygen, nitrogen, acetylene, the pressure of which is held in the range of 10⁻³ to 0.1 mbar by means of vacuum pumps 8 connected to the coating chamber 2. The substrates 4, the cathodes 3 and the anode 5 are connected to DC voltage sources 15, 16, 17, the reference potential of the voltage sources 15, 16, 17 and the potential of the coating chamber 2 being at ground potential. It is customary for potentials of +20 to +200 V to be applied to the anode 5, potentials of −50 to −1000 V to be applied to the cathodes 3 and potentials of 0 to −1000 V to be applied to the substrates 4. As an alternative, the substrates 4 can be insulated or held at floating potential—as indicated by an open switch 23 in FIG. 3. The anode 5 is cooled by a cooling apparatus (not shown).

The anode 5 is additionally connected to a pulsed voltage source 19 connected in parallel with the DC voltage supply. The pulsed voltage source 19 supplies an asymmetrical pulse sequence of positive and negative pulses to the anode 5. A unipolar or bipolar pulsed voltage supply can likewise be involved. A device 24 that can be actuated by means of a switch 25 is positioned in the electrical feed line from the pulsed voltage source 19 to the anode 5, which device, in the switched-on state, permits only positive pulses to pass to the anode 5. The device 24 is for example at least one blocking diode or an arrangement of a plurality of blocking diodes for negative pulses.

The cathodes 3 are illustrated as balanced or unbalanced magnetron sputtering sources in the drawing. Arc evaporator sources (not shown) can also be used instead of magnetron sputtering sources. The magnetron sputtering sources or cathodes 3 are connected to pulsed voltage sources 18, 18 . . . , one of which is illustrated in FIG. 2. The pulsed voltage sources 18, 18, . . . can supply sinusoidal AC voltages, unipolar or bipolar pulsed voltages.

The pulsed voltage sources 18, 19 generate voltages of the order of magnitude of −500 V to +500 V and the frequency of the pulses lies in the range of 5 to 300 kHz.

The material of the anode 5 is selected for example from the group Al, AlCr, ZrN, CrN, TiAlN, the enumeration not in any way being complete, since further nitrides, in particular carbide nitrides, are suitable as anode material. The material of the anode 5 is the same material that is contained in the targets of the cathodes 3.

By means of the pulsed anode 5 and the pulsed cathodes 3, the electron emission is increased, whereby the cathode current and the substrate current are increased. Furthermore, the ionization of the evaporated target material and of the reactive gas is intensified. The substrate surfaces, that is to say the insulating layers that form, are discharged rapidly on account of increased electron density.

In the substrate region, the plasma densifies and the reactivity increases and increased substrate temperatures are obtained.

The cross section illustrated in plan view in FIG. 3a schematically shows the spatial distribution of discharge plasmas 14 in a conventional PVD coating installation with four cathodes 3, which are embodied as balanced magnetrons and each have a target 13 and a permanent magnet set 11 arranged behind the target 13. As indicated by the arrows 20 and 21, the substrate carriers 6 are led past the cathodes 3 on a circular path and simultaneously rotate about their longitudinal axis. In this case, the wall of the coating chamber 2 functions as an anode; as an alternative, separate anodes arranged directly alongside the cathodes 3 are also used (not shown in FIG. 3a). A discharge plasma 14 is ignited at each cathode 3 and extends into a spatial zone in front of the cathode 3. The magnetic field of the permanent magnet set 11 and the electric field—directed substantially perpendicularly thereto—of the cathode potential are superposed in front of the target 13, whereby the discharge plasma 14 is concentrated and virtually completely enclosed in front of the target 13.

FIG. 3b shows a further PVD coating installation of known type with four cathodes 3, which are embodied as balanced magnetrons and are each equipped with an electromagnetic coil 12. By means of the electromagnetic coil 12, an additional magnetic field is generated, the field lines of which run perpendicular to the target 13 and amplify the magnetic field of the outer poles of the permanent magnetic set 11. As a result, the above-described plasma confinement in front of the cathodes 3 is cancelled and the discharge plasma 14 fills the spatial zone in front of the cathodes 3. A cathode which operates according to this principle is generally referred to as an unbalanced magnetron cathode. The strength of the magnetic field generated by the electromagnetic coils 12 determines the feeding-in and expansion of the discharge plasma 14 into the space in front of the cathode 3. Consequently, it is possible to control the density and spatial extent of the discharge plasma 14 in a delimited region by means of the current intensity I_{UB} in the electromagnetic coils 12.

As indicated schematically in FIG. 3b, however, even with unbalanced magnetron cathodes 3 it is not possible to extend the discharge plasmas 14 in such a way that the open regions of the spatial zone 22 are permeated and the substrates 4 are uniformly surrounded by plasma. Particularly if the clearance between adjacent substrate carriers 6 is small, the substrate sides remote from the cathodes 3 are practically completely shielded from the discharge plasmas 14.

FIG. 3c shows a PVD coating installation equipped with a central anode 5 according to the invention. The central anode 5 has the effect that the discharge plasmas 14 extend right into the central region of the coating chamber 2. The discharge plasmas 14 pervade the open regions of the spatial zone 22 and fill the space between the anode 5 and the substrate carriers 6, the substrates 4 being enclosed by discharge plasmas 14. The voltage sources are not depicted in FIG. 3c, for reasons of simplification.

One preferred configuration of the invention is characterized by an arrangement in which the permanent magnet sets 11 and the electromagnetic coils 12 of adjacent cathodes 3 have mutually opposite polarities and generate a closed magnetic field. The spatial extent of this closed magnetic field is illustrated in FIG. 3c by means of inwardly curved lines running in each case from the outer North pole of one permanent magnet set 11 to the outer South poles of the two adjacent permanent magnet sets 11 on the left and right.

Coating installations used industrially have in some instances heights of more than two meters. For the purpose of effectively loading and unloading the substrate batches the coating chamber is equipped with a laterally arranged vacuum door or vacuum lock. Such a vacuum door/lock enables horizontal access to the interior of the coating installation. FIG. 4a schematically shows such an embodiment of the invention in which the coating chamber 2 is equipped with a vertical recipient 9 for receiving the anode 5. The substrate carriers 6 equipped with substrates 4 are mounted on a holding plate or directly on the rotary table 7. For unloading the coating chamber 2, firstly the anode 5 is moved by means of an actuating motor (not shown) from its working position into its loading/unloading position in the recipient 9 in order to give free access to the interior of the coating chamber 2. Afterward the vacuum door/lock (not shown) is opened and the holding plate with the substrate carriers 6 and the substrates 4 is removed horizontally from the coating chamber 2 by means of a charging carriage. For loading the coating chamber 2, the holding plate or the rotary table 7 with the substrate carriers 6 and the substrates 4 to be coated is introduced horizontally into the coating chamber 2 by means of the charging carriage. When a holding plate is used, it is placed onto the rotary table 7. Afterward, the vacuum door/lock is closed, the coating chamber 2 is evacuated, the anode 5 is moved to its working position and the coating process is started.

In order to protect the anode 5 against contamination during the ventilation of the coating chamber 2, it is expedient to equip the recipient 9 with a valve (not shown).

FIG. 4b, the reference numerals of which are analogous to those of FIG. 4a shows a further configuration of the invention, in which an anode 5′ has a telescopic construction. Before the coating chamber 2 is loaded/unloaded, the anode 5′ is telescopically retracted. This makes it possible to reduce the structural height of the recipient 9 in comparison with the embodiment according to FIG. 4a, or to completely dispense with the recipient 9.

1. A vacuum coating installation for homogeneous PVD coating of three-dimensional substrates comprising
a coating chamber,
two or more magnetron sputtering sources or arc evaporator sources arranged peripherally within the coating chamber,
a substrate carrier for holding the substrate,
vacuum pumps and voltage sources,
wherein an individual, central anode is connected to a pulsed voltage source and the respective magnetron sputtering sources or arc evaporator sources are connected to pulsed voltage sources.

2. The vacuum coating installation as claimed in claim 1, wherein the magnetron sputtering sources or arc evaporator sources are connected to DC voltage sources.

3. The vacuum coating installation as claimed in claim 1, wherein the pulsed voltage source supplies the anode with an asymmetrical pulse sequence of positive and negative pulses.

4. The vacuum coating installation as claimed in claim 1, wherein a switchable device that permits only positive pulses to pass is positioned in the electrical feed line from the pulsed voltage source to the anode.

5. The vacuum coating installation as claimed in claim 1, wherein the switchable device contains at least one blocking diode for negative pulses.

6. The vacuum coating installation as claimed in claim 1, wherein the pulsed voltage sources generate voltages in the range of −500 V to +500 V.

7. The vacuum coating installation as claimed in claim 1, wherein the frequency of the pulsed voltage sources lies in the range of 5 to 300 kHz.

8. The vacuum coating installation as claimed in claim 1, wherein the material of the anode is Al, AlCr, ZrN, CrN, TiAlN.

9. The vacuum coating installation as claimed in claim 1, wherein the material of the anode is the same material that is contained in the cathode targets.

10. The vacuum coating installation as claimed in claim 8, wherein the anode is covered with a graphite sheath.
